(19) United States
(12) Patent Application Publication
(10) Pub. No.: US 2009/0124087 A1
(43) Pub. Date: May 14, 2009

(54) Vertical plasma processing apparatus and method for using same

(76) Inventors: Nobutake Nodera, Nirasaki-shi (JP); Jun Sato, Nirasaki-shi (JP); Masanobu Matsunaga, Nirasaki-shi (JP); Kazuhide Hasebe, Nirasaki-shi (JP); Hisashi Inoue, Tokyo (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/285,885

(22) Filed: Oct. 15, 2008

(30) Foreign Application Priority Data
Oct. 19, 2007 (JP) 2007-272626

(51) Int. Cl. H01L 21/3065; H01L 21/28; C23C 16/00; C23F 1/08

(52) U.S. Cl. 438/710; 118/723 R; 156/345.43; 438/786; 438/791; 438/787; 257/E21.218; 257/E21.211; 257/E21.293; 257/E21.271; 257/E21.24

(57) ABSTRACT

A vertical plasma processing apparatus for a semiconductor process for performing a plasma process on target substrates all together includes an exciting mechanism configured to turn at least part of a process gas into plasma. The exciting mechanism includes first and second electrodes provided to a plasma generation box and facing each other with a plasma generation area interposed therebetween, and an RF power supply configured to supply an RF power for plasma generation to the first and second electrodes and including first and second output terminals serving as grounded and non-grounded terminals, respectively. A switching mechanism is configured to switch between a first state where the first and second electrodes are connected to the first and second output terminals, respectively, and a second state where the first and second electrodes are connected to the second and first output terminals, respectively.

### BACKGROUND OF THE INVENTION

1. Field of the Invention

The present invention relates to a vertical plasma processing apparatus for a semiconductor process for performing a plasma process on a plurality of target substrates, such as semiconductor wafers, all together, and a method for using the same. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or a glass substrate used for an FPD (Flat Panel Display), e.g., an LCD (Liquid Crystal Display), by forming semiconductor layers, insulating layers, and conductive layers in predetermined patterns on the target substrate.

2. Description of the Related Art

In manufacturing semiconductor devices for constituting semiconductor integrated circuits, a target substrate, such as a semiconductor wafer, is subjected to various processes, such as film formation, etching, oxidation, diffusion, reformation, annealing, and natural oxide film removal. US 2006/0286817 A1 discloses a semiconductor processing method of this kind performed in a vertical heat-processing apparatus (of the so-called batch type). According to this method, semiconductor wafers are first transferred from a wafer cassette onto a vertical wafer boat and supported thereon at intervals in the vertical direction. The wafer cassette can store, e.g., 25 wafers, while the wafer boat can support 30 to 150 wafers. Then, the wafer boat is loaded into a process container from below, and the process container is airtightly closed. Then, a predetermined heat process is performed, while the process conditions, such as process gas flow rate, process pressure, and process temperature, are controlled.

In order to improve the performance of semiconductor integrated circuits, it is important to improve properties of insulating films used in semiconductor devices. Semiconductor devices include insulating films made of materials, such as SiO₂, PSG (Phospho Silicate Glass), P-SiO (formed by plasma CVD), P-SiN (formed by plasma CVD), and SOG (Spin On Glass), Si₃N₄ (silicon nitride). Particularly, silicon nitride films are widely used, because they have better insulation properties as compared to silicon oxide films, and they can sufficiently serve as etching stopper films or inter-level insulating films. Further, for the same reason, carbon nitride films doped with boron are sometimes used.

Several methods are known for forming a silicon nitride film on the surface of a semiconductor wafer by thermal CVD (Chemical Vapor Deposition). In such thermal CVD, a silane family gas, such as monosilane (SiH₄), dichlorosilane (DCS: SiH₂Cl₂), hexachloro-disilane (HCD: Si₂Cl₆), bistertialbutylaminosilane (BTBAS: SiH₂(NH(C₄H₉))₂), or (t-C₄H₉NH)₂SiH₂, is used as a silicon source gas. For example, a silicon nitride film is formed by thermal CVD using a gas combination of SiH₂Cl₂+NH₃ (see U.S. Pat. No. 5,874,368 A) or Si₂Cl₆+NH₃. Further, there is also proposed a method for doping a silicon nitride film with an impurity, such as boron (B), to decrease the dielectric constant.

In recent years, owing to the demands of increased miniaturization and integration of semiconductor integrated circuits, it is required to alleviate the thermal history of semiconductor devices in manufacturing steps, thereby improving the characteristics of the devices. For vertical processing apparatuses, it is also required to improve semiconductor processing methods in accordance with the demands described above. For example, there is a CVD (Chemical Vapor Deposition) method for a film formation process, which performs film formation while intermittently supplying a source gas and so forth to repeatedly form layers each having an atomic or molecular level thickness, one by one, or several by several (for example, Jpn. Pat. Appln. KOKAI Publications No. 2-93071 and No. 6-45256 and U.S. Pat. No. 6,165,916 A). In general, this film formation process is called ALD (Atomic layer Deposition) or MLD (Molecular Layer Deposition), which allows a predetermined process to be performed without exposing wafers to a very high temperature.

As a film formation apparatus for performing a film formation process of the kind described above, there has been proposed a vertical film formation apparatus that utilizes plasma (for example, Jpn. Pat. Appln. KOKAI Publication No. 2006-287194). This film formation apparatus includes a vertical process container and a gas exciting section comprising a vertically long narrow cover (plasma generation box) attached along one side of the process container. A pair of electrodes are disposed outside the cover and are supplied with an RF power. A gas distribution nozzle is disposed inside the gas exciting section to supply a gas, such as NH₃ gas, which is to be turned into plasma.

For example, where dichlorosilane (DCS) and NH₃ are supplied as a silane family gas and a nitriding gas, respectively, to form a silicon nitride film (SiN), the process is performed, as follows. Specifically, DCS and NH₃ gas are alternately and intermittently supplied into a process container with purge periods interposed therebetween. When NH₃ gas is supplied, an RF (radio frequency) is applied to generate plasma within the process container so as to promote a nitridation reaction. More specifically, when DCS is supplied into the process container, a layer with a thickness of one molecule or more of DCS is adsorbed onto the surface of wafers. The superfluous DCS is removed during the purge period. Then, NH₃ is supplied and plasma is generated, thereby performing low temperature nitridation to form a silicon nitride film. These sequential steps are repeated to complete a film having a predetermined thickness.

However, as described later, the present inventors have found that conventional film formation apparatuses of this kind have room for improvement in terms of some characteristics of the apparatus concerning the throughput and particle generation.

### BRIEF SUMMARY OF THE INVENTION

An object of the present invention is to provide a vertical plasma processing apparatus for a semiconductor process and a method for using the same, which can improve characteristics of the apparatus concerning the throughput and particle generation.

According to a first aspect of the present invention, there is provided a vertical plasma processing apparatus for a semiconductor process for performing a plasma process on a plurality of target substrates all together, the apparatus comprising: a vertically elongated process container having a process field configured to accommodate the target substrates and to be set in an airtight state; a holder configured to support the target substrates at intervals in a vertical direction inside the process container; a gas supply system configured to supply a process gas into the process container; an exhaust system configured to exhaust gas from inside the process container; and an exciting mechanism configured to turn at least part of the process gas into plasma, wherein the exciting mechanism comprises a plasma generation box attached to the process container at a position corresponding to the process field to form a plasma generation area airtightly communicating with the process field, first and second electrodes provided to the plasma generation box and facing each other with the plasma generation area interposed therebetween, an RF (radio frequency) power supply configured to supply an RF power for plasma generation to the first and second electrodes and comprising first and second output terminals serving as grounded and non-grounded terminals, respectively, first and second feed lines connecting the first and second electrodes to the first and second output terminals, and a switching mechanism configured to switch between a first state where the first electrode is connected to the first output terminal and the second electrode is connected to the second output terminal, and a second state where the first electrode is connected to the second output terminal and the second electrode is connected to the first output terminal.

According to a second aspect of the present invention, there is provided a method for using a vertical plasma processing apparatus for a semiconductor process for performing a plasma process on a plurality of target substrates all together, the apparatus comprising a vertically elongated process container having a process field configured to accommodate the target substrates and to be set in an airtight state, a holder configured to support the target substrates at intervals in a vertical direction inside the process container, a gas supply system configured to supply a process gas into the process container, an exhaust system configured to exhaust gas from inside the process container, and an exciting mechanism configured to turn at least part of the process gas into plasma, wherein the exciting mechanism comprises a plasma generation box attached to the process container at a position corresponding to the process field to form a plasma generation area airtightly communicating with the process field, first and second electrodes provided to the plasma generation box and facing each other with the plasma generation area interposed therebetween, an RF (radio frequency) power supply configured to supply an RF power for plasma generation to the first and second electrodes and comprising first and second output terminals serving as grounded and non-grounded terminals, respectively, and first and second feed lines connecting the first and second electrodes to the first and second output terminals, the method comprising: performing a semiconductor process on the target substrates inside the process field by supplying the process gas to the process field while exciting at least part of the process gas into plasma by the exciting mechanism; and switching between a first state where the first electrode is connected to the first output terminal and the second electrode is connected to the second output terminal, and a second state where the first electrode is connected to the second output terminal and the second electrode is connected to the first output terminal, each of which is used as a state of the exciting mechanism for exciting at least part of the process gas into plasma.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view showing a film formation apparatus (vertical CVD apparatus) according to an embodiment of the present invention;

FIG. 2 is a sectional plan view showing part of the apparatus shown in FIG. 1;

FIG. 3 is a circuit diagram showing an RF circuit for supplying an RF power to electrodes in the apparatus shown in FIG. 1;

FIG. 4 is a timing chart showing the gas supply and RF (radio frequency) application of a film formation process according to an embodiment of the present invention;

FIG. 5 is a graph showing the relationship of the number of particles and cumulative film thickness relative to the number of batch processes in a comparative example (a conventional usage method) in which the electrodes underwent no switching between the hot side (non-grounded state) and ground side (grounded state);

FIG. 6 is a graph showing the relationship of the number of particles and cumulative film thickness relative to the number of batch processes in a present example (a usage method according to the embodiment of the present invention) in which the electrodes underwent switching between the hot side and ground side; and

FIG. 7 is a graph showing the gas type dependency of the amount of etching to the quartz cover of the gas exciting section.

### DETAILED DESCRIPTION OF THE INVENTION

In the process of developing the present invention, the inventors studied problems with regard to conventional vertical plasma processing apparatuses for semiconductor processes and methods for using the same. As a result, the inventors have arrived at the findings given below.

Specifically, in film formation apparatus of this kind, the gas exciting section for generating plasma is defined by a cover made of, e.g., quartz (SiO₂). The inner surface of the SiO₂ cover is sputtered by ions activated by plasma, and so the inner surface is etched and SiO₂ particles generated from the etched portion are re-deposited on the inner surface. Further, the SiO₂ particles thus re-deposited are nitrided by activated NH₃, and by-product films of various substances, such as SiO₂ and SiON, are deposited on the inner surface of the cover. These deposits inside the gas exciting section may be causes of particle generation.

In light of this problem, a cleaning process for removing unnecessary deposits from inside the reaction tube and gas exciting section is performed to prevent particles from being generated from the gas exciting section. The cleaning process is performed when the cumulative film thickness of product films formed on target substrates reaches a predetermined value, or at regular intervals or irregular intervals. However, the frequency of the cleaning process needs to be relatively high, inevitably resulting in an increase in the downtime of the apparatus (a decrease in the throughput of the process).

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

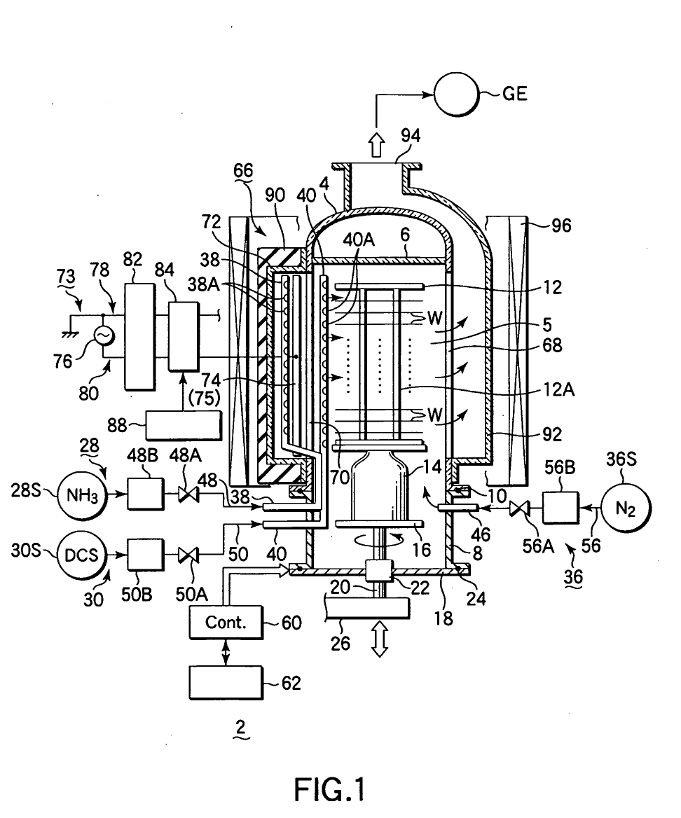

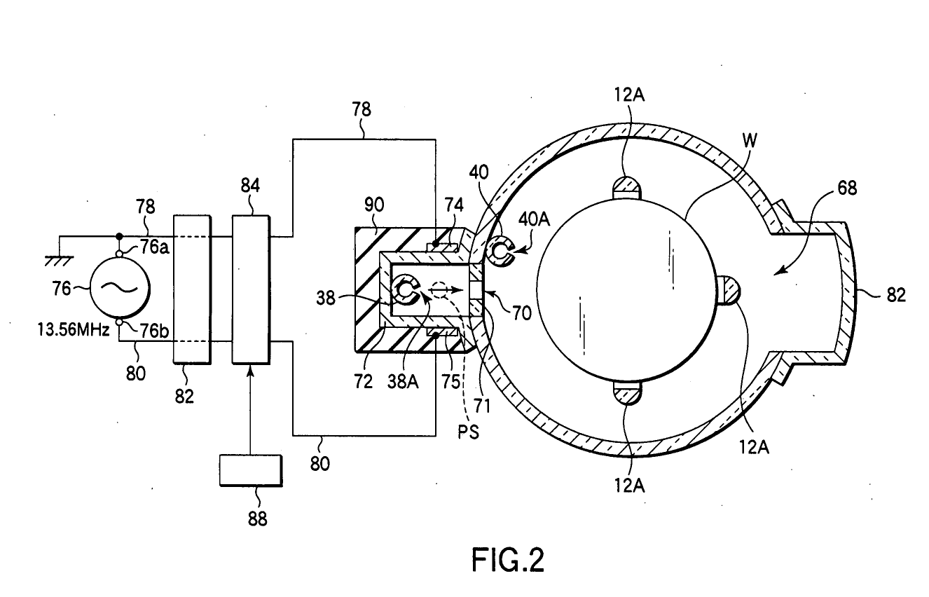

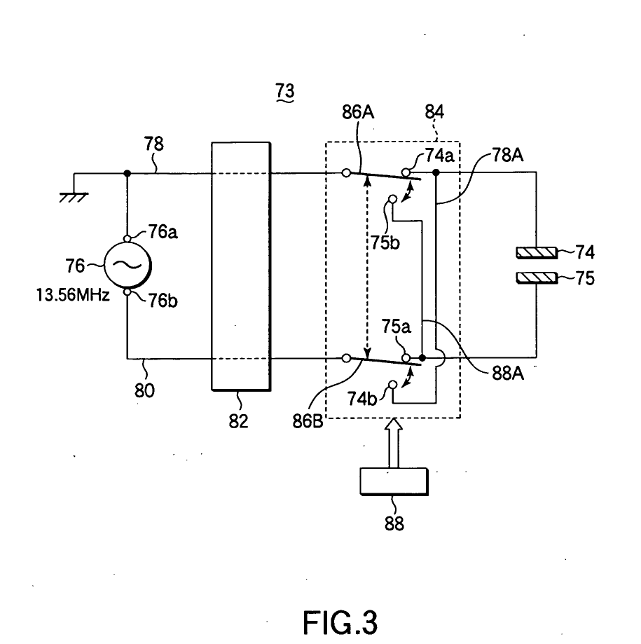

FIG. 1 is a sectional view showing a film formation apparatus (vertical CVD apparatus) according to an embodiment of the present invention. FIG. 2 is a sectional plan view showing part of the apparatus shown in FIG. 1. FIG. 3 is a circuit diagram showing an RF circuit for supplying an RF power to electrodes in the apparatus shown in FIG. 1. The film formation apparatus 2 has a process field configured to be selectively supplied with a first process gas containing dichlorosilane (DCS) gas as a silane family gas, and a second process gas containing ammonia (NH₃) gas as a nitriding gas. The film formation apparatus 2 is configured to form a silicon nitride film on target substrates in the process field.

The apparatus 2 includes a process container 4 shaped as a cylindrical column with a ceiling and an opened bottom, in which a process field 5 is defined to accommodate and-process a plurality of semiconductor wafers (target substrates) stacked at intervals in the vertical direction. The entirety of the process container 4 is made of, e.g., quartz. The top of the process container 4 is provided with a quartz ceiling plate 6 to airtightly seal the top. The bottom of the process container 4 is connected through a seal member 10, such as an O-ring, to a cylindrical manifold 8. The process container may be entirely formed of a cylindrical quartz column without a manifold 8 separately formed.

The manifold 8 is made of, e.g., stainless steel, and supports the bottom of the process container 4. A wafer boat 12 made of quartz is moved up and down through the bottom port of the manifold 8, so that the wafer boat 12 is loaded/unloaded into and from the process container 4. A number of target substrates or semiconductor wafers W are stacked on the wafer boat 12. For example, in this embodiment, the wafer boat 12 has struts 12A that can support, e.g., about 50 to 100 wafers having a diameter of 300 mm at essentially regular intervals in the vertical direction.

The wafer boat 12 is placed on a table 16 through a heat-insulating cylinder 14 made of quartz. The table 16 is supported by a rotary shaft 20, which penetrates a lid 18 made of, e.g., stainless steel, and is used for opening/closing the bottom port of the manifold 8.

The portion of the lid 18 where the rotary shaft 20 penetrates is provided with, e.g., a magnetic-fluid seal 22, so that the rotary shaft 20 is rotatably supported in an airtightly sealed state. A seal member 24, such as an O-ring, is interposed between the periphery of the lid 18 and the bottom of the manifold 8, so that the interior of the process container 4 can be kept sealed.

The rotary shaft 20 is attached at the distal end of an arm 26 supported by an elevating mechanism 25, such as a boat elevator. The elevating mechanism 25 moves the wafer boat 12 and lid 18 up and down integratedly. The table 16 may be fixed to the lid 18, so that wafers W are processed without rotation of the wafer boat 12.

A gas supply section is connected to the side of the manifold 8 to supply predetermined process gases to the process field 5 within the process container 4. Specifically, the gas supply section includes a second process gas supply circuit 28, a first process gas supply circuit 30, and a purge gas supply circuit 36. The first process gas supply circuit 30 is arranged to supply a first process gas containing a silane family gas, such as DCS (dichlorosilane) gas. The second process gas supply circuit 28 is arranged to supply a second process gas containing a nitriding gas, such as ammonia (NH₃) gas. The purge gas supply circuit 36 is arranged to supply an inactive gas, such as N₂ gas, as a purge gas. Each of the first and second process gases is mixed with a suitable amount of carrier gas, as needed. However, such a carrier gas will not be mentioned, hereinafter, for the sake of simplicity of explanation.

More specifically, the second and first process gas supply circuits 28 and 30 include gas distribution nozzles 38 and 40, respectively, each of which is formed of a quartz pipe which penetrates the sidewall of the manifold 8 from the outside and then turns and extends upward (see FIG. 1). The gas distribution nozzles 38 and 40 respectively have a plurality of gas spouting holes 38A and 40A, each set of holes being formed at predetermined intervals in the longitudinal direction (the vertical direction) over all the wafers W on the wafer boat 12. Each set of the gas spouting holes 38A and 40A deliver the corresponding process gas almost uniformly in the horizontal direction, so as to form gas flows parallel with the wafers W on the wafer boat 12. The purge gas supply circuit 36 includes a short gas nozzle 46, which penetrates the sidewall of the manifold 8 from the outside.

The nozzles 38, 40, and 46 are connected to gas sources 28S, 30S, and 36S of NH₃ gas, DCS gas, and N₂ gas, respectively, through gas supply lines (gas passages) 48, 50, and 56, respectively. The gas supply lines 48, 50, and 56 are provided with switching valves 48A, 50A, and 56A and flow rate controllers 48B, 50B, and 56B, such as mass flow controllers, respectively. With this arrangement, NH₃ gas, DCS gas, and N₂ gas can be supplied at controlled flow rates.

A gas exciting section 66 is formed on the sidewall of the process container 4 in the vertical direction. On the side of the process container 4 opposite to the gas exciting section 66, a long narrow exhaust port 68 for vacuum-exhausting the inner atmosphere is formed by cutting the sidewall of the process container 4 in, e.g., the vertical direction.

Specifically, the gas exciting section 66 has a vertically long narrow opening formed by cutting a predetermined width of the sidewall of the process container 4, in the vertical direction. This opening is closed by a partition plate 71 having a vertically long slit 70, and is further covered with a quartz cover (plasma generation box) 72 airtightly connected to the outer surface of the process container 4 by welding. The cover 72 has a vertically long narrow shape with a concave cross-section, so that it projects outward from the process container 4.

With this arrangement, the gas exciting section 66 is formed such that it projects outward from the sidewall of the process container 4 and is opened on the other side to the interior of the process container 4. In other words, the inner space of the gas exciting section 66 communicates with the process field 5 within the process container 4 through the slit 70. The slit 70 has a vertical length sufficient to cover all the wafers W on the wafer boat 12 in the vertical direction.

A pair of long narrow electrodes 74 and 50 are disposed on the opposite outer surfaces of the cover 72, and face each other while extending in the longitudinal direction (the vertical direction). The electrodes 74 and 75 are connected to first and second output terminals 76a and 76b of an RF (Radio Frequency) power supply 76 for plasma generation through feed lines 78 and 80, so that an RF circuit 73 is constituted, as shown in FIGS. 2 and 3. An RF voltage of, e.g., 13.56 MHz is applied from the RF power supply 76 to the electrodes 74 and 50 to form an RF electric field for exciting plasma between the electrodes 74 and 50. The frequency of the RF voltage is not limited to 13.56 MHz, and it may be set at another frequency, e.g., 400 kHz. A plurality of pairs of electrodes 74 and 75 may be used in place of one pair.

The RF circuit 73 is preset such that the first and second output terminals 76a and 76b of the RF power supply 76 are a grounded terminal (ground side) and a non-grounded terminal (hot side), respectively. The feed lines 78 and 80 are provided with a matching circuit 82 and a switching circuit 84 in this order from the RF power supply 76 side. The matching circuit 82 includes therein a coil and a variable capacitor to perform impedance matching in the RF circuit 78.

The switching circuit 84 includes switches 86A and 86B disposed on the feed lines 78 and 80 and interlocked with each other. One 86A of the switches is switchable between a terminal 74a connected to the electrode 74 and a terminal 75b connected to the electrode 75 through a branch line 80A. The other 86B of the switches is switchable between a terminal 75a connected to the electrode 75 and a terminal 74b connected to the electrode 74 through a branch line 78A.

The switches 86A and 86B are simultaneously switched in an interlock manner, so that the electrodes 74 and 75 are switched between the ground side and hot side. The ground side of an electrode means a state where the electrode is connected to the first output terminal (grounded terminal) 76a of the RF power supply 76. The hot side of an electrode means a state where the electrode is connected to the second output terminal (non-grounded terminal) 76b of the RF power supply 76. For example, when the switches 86A and 86B are set in the state shown in FIG. 3, the electrode 74 is on the ground side while the electrode 75 is on the hot side.

A switching controller 88 is disposed to control an operation of the switching circuit 84. The switching controller 88 works under the control of a main control section 60 described later (see FIG. 1). The switching circuit 84 may have a mechanical structure using, e.g., electromagnetic relays, or an electronic structure using switching elements, such as transistors. However, the switching circuit 84 can be any circuit as long as the two electrodes 74 and 75 are switchable between the ground side and hot side.

Back to FIG. 1, the gas distribution nozzle 38 of the second process gas is bent outward in the radial direction of the process container 4, at a position lower than the lowermost wafer W on the wafer boat 12. Then, the gas distribution nozzle 38 vertically extends at the deepest position (the farthest position from the center of the process container 4) in the gas exciting section 66. As shown also in FIG. 2, the gas distribution nozzle 38 is separated outward from an area sandwiched between the pair of electrodes 74 and 50 (a position where the RF electric field is most intense), i.e., a plasma generation area PS where the main plasma is actually generated. The second process gas containing NH₃ gas is spouted from the gas spouting holes 38A of the gas distribution nozzle 38 toward the plasma generation area PS. Then, the second process gas is selectively excited (decomposed or activated) in the plasma generation area PS, and is supplied in this state onto the wafers W on the wafer boat 12.

An insulating protection cover 90 made of, e.g., quartz is attached on and covers the outer surface of the cover 72. A cooling mechanism (not shown) is disposed in the insulating protection cover 90 and comprises coolant passages respectively facing the electrodes 74 and 50. The coolant passages are supplied with a coolant, such as cooled nitrogen gas, to cool the electrodes 74 and 50. The insulating protection cover 90 is covered with a shield (not shown) disposed on the outer surface to prevent RF leakage.

At a position near and outside the slit 70 of the gas exciting section 66, the gas distribution nozzle 40 of the first process gas is disposed. Specifically, the gas distribution nozzle 40 extends upward on one side of the outside of the slit 70 (in the process container 4). The first process gas containing DCS gas is spouted from the gas spouting holes 40A of the gas distribution nozzle 40 toward the center of the process container 4.

On the other hand, the exhaust port 68, which is formed opposite the gas exciting section 66, is covered with an exhaust port cover member 92. The exhaust port cover member 92 is made of quartz with a U-shape cross-section, and attached by welding. The exhaust cover member 92 extends upward along the sidewall of the process container 4, and has a gas outlet 94 at the top of the process container 4. The gas outlet 94 is connected to a vacuum-exhaust system GE including a vacuum pump and so forth.

The process container 4 is surrounded by a heater 96, which is used for heating the atmosphere within the process container 4 and the wafers W. A thermocouple (not shown) is disposed near the exhaust port 68 in the process container 4 to control the heater 96.

The film formation apparatus 2 further includes a main control section 60 formed of, e.g., a computer, to control the entire apparatus. The main control section 60 can control a film formation process as described below in accordance with process recipes stored in the storage section 62 thereof in advance, with reference to the film thickness and composition of a film to be formed. In the storage section 62, the relationship between the process gas flow rates and the thickness and composition of the film is also stored as control data in advance. Accordingly, the main control section 60 can control the elevating mechanism 25, gas supply circuits 28, 30, and 36, exhaust system GE, gas exciting section 66, heater 96, and so forth, based on the stored process recipes and control data. Examples of a storage medium are a magnetic disk (flexible disk, hard disk (a representative of which is a hard disk included in the storage section 62), etc.), an optical disk (CD, DVD, etc.), a magneto-optical disk (MO, etc.), and a semiconductor memory.

Next, an explanation will be given of a film formation process (so called ALD or MLD film formation) performed in the apparatus shown in FIG. 1. In this film formation process, a silicon nitride film is formed on semiconductor wafers by ALD or MLD. In order to achieve this, a first process gas containing dichlorosilane (DCS) gas as a silane family gas and a second process gas containing ammonia (NH₃) gas as a nitriding gas are selectively supplied into the process field 5 accommodating wafers W. Specifically, a film formation process is performed along with the following operations.

<Film Formation Process>

At first, the wafer boat 12 at room temperature, which supports a number of, e.g., 50 to 100, wafers having a diameter of 300 mm, is loaded into the process container 4 heated at a predetermined temperature, and the process container 4 is airtightly closed. Then, the interior of the process container 4 is vacuum-exhausted and kept at a predetermined process pressure, and the wafer temperature is increased to a process temperature for film formation. At this time, the apparatus is in a waiting state until the temperature becomes stable. Then, while the wafer boat 12 is rotated, the first and second process gases are intermittently supplied from the respective gas distribution nozzles 40 and 38 at controlled flow rates.

The first process gas containing DCS gas is supplied from the gas spouting holes 40A of the gas distribution nozzle 40 to form gas flows parallel with the wafers W on the wafer boat 12. While being supplied, the DCS gas is activated by the heating temperature to the process field 5, and molecules of the DCS gas and molecules and atoms of decomposition products generated by decomposition are adsorbed on the wafers W.

On the other hand, the second process gas containing NH₃ gas is supplied from the gas spouting holes 38A of the gas distribution nozzle 38 to form gas flows parallel with the wafers W on the wafer boat 12. When the second process gas is supplied, the gas exciting section 66 is set in the ON-state, as described later.

When the gas exciting section 66 is set in the ON-state, the second process gas is excited and partly turned into plasma when it passes through the plasma generation area PS between the pair of electrodes 74 and 50. At this time, for example, radicals (activated species), such as N*, NH*, NH₂*, and NH₃*, are produced (the symbol ┌*┘ denotes that it is a radical). The radicals flow out from the slit 70 of the gas exciting section 66 toward the center of the process container 4, and are supplied into gaps between the wafers W in a laminar flow state.

The radicals react with molecules and so forth of DCS gas adsorbed on the surface of the wafers W, so that a thin film of silicon nitride is formed on the wafers W. Alternatively, when the DCS gas flows onto radicals derived from the NH₃ gas and adsorbed on the surface of the wafers W, the same reaction is caused, so a thin film of silicon nitride is formed on the wafers W.

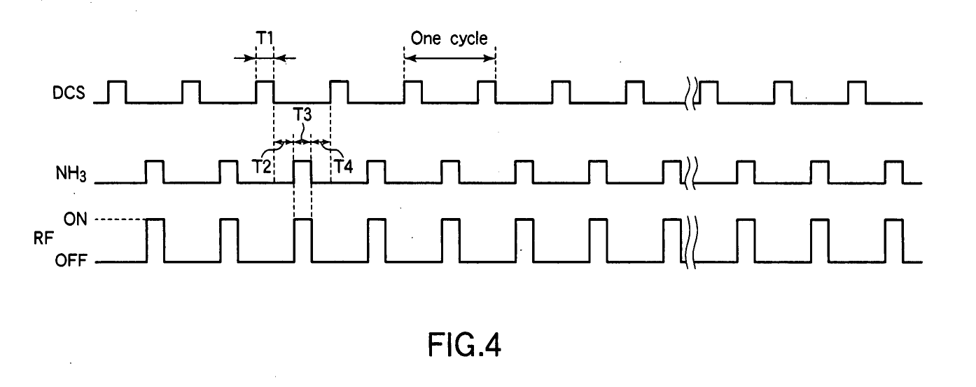

FIG. 4 is a timing chart showing the gas supply and RF (radio frequency) application of a film formation process according to an embodiment of the present invention. As shown in FIG. 4, the film formation process according to this embodiment alternately repeats first to fourth steps T1 to T4. A cycle comprising the first to fourth steps T1 to T4 is repeated a number of times, and thin films of silicon nitride formed by respective times are laminated, thereby arriving at a silicon nitride film having a target thickness.

Specifically, the first step T1 is arranged to perform supply of the first process gas (denoted as DCS in FIG. 4) to the process field 5, while maintaining the shut-off state of supply of the second process gas (denoted as NH₃ in FIG. 4) to the process field 5. The second step T2 is arranged to maintain the shut-off state of supply of the first and second process gases to the process field 5. The third step T3 is arranged to perform supply of the second process gas to the process field 5, while maintaining the shut-off state of supply of the first process gas to the process field 5. Further, in the third step T3, the RF power supply 76 is set in the ON-state to turn the second process gas into plasma by the gas exciting section 66, so as to supply the second process gas in an activated state to the process field 5. The fourth step T4 is arranged to maintain the shut-off state of supply of the first and second process gases to the process field 5.

Each of the second and fourth steps T2 and T4 is used as a purge step to remove the residual gas within the process container 4. The term “purge” means removal of the residual gas within the process container 4 by vacuum-exhausting the interior of the process container 4 while supplying an inactive gas, such as N₂ gas, into the process container 4, or by vacuum-exhausting the interior of the process container 4 while maintaining the shut-off state of supply of all the gases. In this respect, the second and fourth steps T2 and T4 may be arranged such that the first half utilizes only vacuum-exhaust and the second half utilizes both vacuum-exhaust and inactive gas supply. Further, the first and third steps T1 and T3 may be arranged to stop vacuum-exhausting the process container 4 while supplying each of the first and second process gases. However, where supplying each of the first and second process gases is performed along with vacuum-exhausting the process container 4, the interior of the process container 4 can be continuously vacuum-exhausted over the entirety of the first to fourth steps T1 to T4.

The third step T3 may be modified such that, halfway through the third step T3, the RF power supply 76 is set in the ON-state to supply the second process gas in an activated state to the process field 5 only during a latter half period. According to this modification, in the third step T3, the RF power supply 76 is turned on after a predetermined time At passes, to turn the second process gas into plasma by the gas exciting section 66, so as to supply the second process gas in an activated state to the process field 5 during the latter half period. The predetermined time At is defined as the time necessary for stabilizing the flow rate of NH₃ gas, which is set at, e.g., about 5 seconds. Since the RF power supply is turned on to generate plasma after the flow rate of the second process gas is stabilized, the uniformity of radical concentration among the wafers W (uniformity in the vertical direction) is improved.

In FIG. 4, the first step T1 is set to be within a range of about 2 to 10 seconds, the second step T2 is set to be within a range of about 5 to 15 seconds, the third step T3 is set to be within a range of about 10 to 20 seconds, and the fourth step T4 is set to be within a range of about 5 to 15 seconds. The film thickness obtained by one cycle of the first to fourth steps T1 to T4 is about 0.11 to 0.13 nm. Accordingly, for example, where the target film thickness obtained by one batch process is 50 nm, the cycle is repeated about 450 times. However, these values of time and thickness are merely examples and thus are not limiting. One batch process is a process performed on a batch of wafers all together between loading and unloading of the wafers.

<Switching of Electrodes>

In a first state where the switches 86A and 86B are respectively connected to the terminals 74a and 75a, as shown in FIG. 3, the electrode 74 is on the ground side while the electrode 75 is on the hot side. On the other hand, in a second state where the switches 86A and 86B are respectively connected to the terminals 75b and 74b, the electrode 74 is on the hot side while the electrode 75 is on the ground side. In order to switch the electrodes 74 and 75 between the first and second states, the main control section 60 causes the controller 88 to switch the switches 86A and 86B of the switching circuit 84, as follows. For example, in one batch process that repeats the cycle described above a predetermined number of times, switching of the switches 86A and 86B may be performed every time one cycle or several cycles are finished. Alternatively, switching of the switches 86A and 86B may be performed every time one batch process is finished, without performing the switching during one batch process that repeats the cycle described above a predetermined number of times. Alternatively, switching of the switches 86A and 86B may be performed every time a predetermined number of batch processes are finished.

In conventional apparatuses, the ground side and hot side of the electrodes 74 and 75 are always stationary, and the quartz cover 72 is sputtered only on a portion on the hot side. Accordingly, a lot of deposits tend to be generated on and around this portion, and so a cleaning process needs to be performed with relatively high frequency. On the other hand, according to this embodiment, the feed lines 78 and 80 connected to the electrodes 74 and 75 of the gas exciting section 66 are provided with the switching circuit 84, so that the electrodes 74 and 75 can be switched between the ground side and hot side with suitable timing. In this case, deposits are prevented from being generated in large quantity only at a portion near one of the electrodes inside the quartz cover 72, and are averaged at portions near both of the electrodes. Consequently, the frequency of the cleaning process can be lower, resulting in a decrease in the downtime of the apparatus (an increase in the throughput of the process).

This advantage is due to the following reason. Specifically, the electric potential of one of the electrodes 74 and 75 set on the ground side becomes a flat ground potential in principle, while the electric potential of the other electrode set on the hot side swings with large amplitude corresponding to the RF power. In this case, the inner surface portion of the quartz cover 72 corresponding to the electrode set on the hot side is repeatedly and fiercely sputtered and thereby etched by ions of plasma. At the same time, SiO₂ particles or SiO₂ molecules thus generated from the etched portion are re-deposited and nitrided, and so a lot of unnecessary deposits are generated on the inner surface portion of the quartz cover 72 corresponding to the electrode set on the hot side. On the other hand, the inner surface portion of the quartz cover 72 corresponding to the electrode set on the ground side does not suffer such actions, and so unnecessary deposits are less generated thereon.

When unnecessary deposits are increased to have a certain film thickness or more, they partly peel off and generate particles. Accordingly, by switching the electrodes between the hot side and ground side to prevent unnecessary deposits from locally and preferentially growing, cleaning intervals can be prolonged, i.e., the frequency of the cleaning process can be decreased.

<Experiment 1>

In the apparatus shown in FIG. 1, a process for forming a silicon nitride film was consecutively performed on a plurality of batches of wafers, and particle generation was examined. In a comparative example, totally 20 batch processes were performed without switching of the electrodes 74 and 75 of the gas exciting section 66 between the ground side and hot side in accordance with conventional techniques. In a present example according to the embodiment described above, totally 29 batch processes were performed with switching of the electrodes 74 and 75 of the gas exciting section 66 between the ground side and hot side, wherein the switching was done after the 17th batch process corresponding to a cumulative film thickness of about 0.8 μm. In each batch process, the process was performed on 100 wafers at a temperature of 630° C. to attain a film thickness of 50 nm. After each batch process, the number of particles was measured on wafers at the top, center, and bottom of the wafer boat. The number of particles was the total number of particles having a size of 80 nm or more. It should be noted that the comparative example and the present example employed the same conditions for each batch process and differed from each other in the total number of batch processes and the switching of the electrodes 74 and 75 between the ground side and hot side.

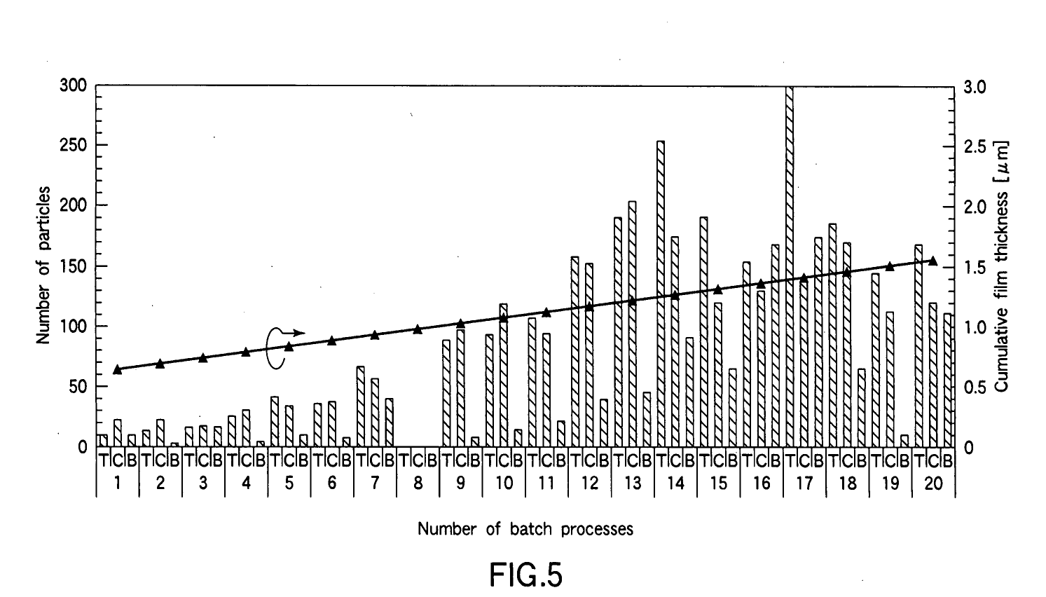

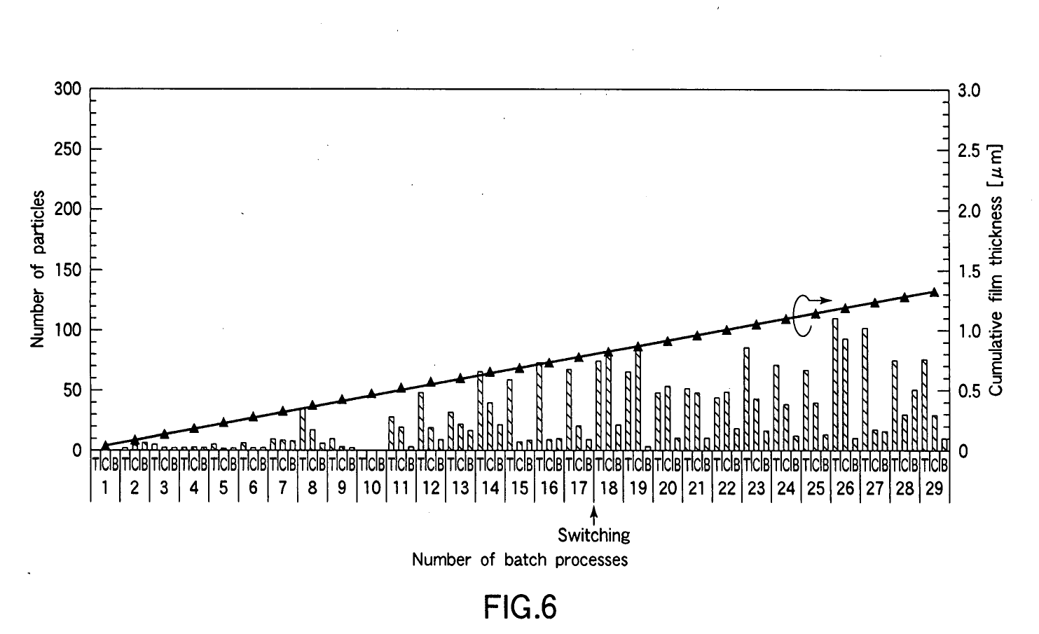

FIG. 5 is a graph showing the relationship of the number of particles and cumulative film thickness relative to the number of batch processes in the comparative example. FIG. 6 is a graph showing the relationship of the number of particles and cumulative film thickness relative to the number of batch processes in the present example. In FIGS. 5 and 6, the left vertical axis denotes the number of particles, and the right vertical axis denotes the cumulative film thickness. Further, in FIGS. 5 and 6, the bar chart represents the number of particles, the line chart represents the cumulative film thickness. The symbols “T”, “C”, and “B” respectively denote wafers at the top, center, and bottom of the wafer boat.

In the comparative example shown in FIG. 5, the 10th batch process corresponding to a cumulative film thickness of about 1.0 μm rendered a number of particles larger than 100. The batch processes performed thereafter mostly rendered a number of particles larger 100. Particularly, the 12th, 13th, 14th, and 17th batch processes rendered extremely large numbers of particles.

In the present example shown in FIG. 6, 18th to 29th batch processes, which were performed after the ground side and hot side of the electrodes 74 and 75 were switched, rendered suppression of particle generation. In these batch processes, good results were brought about with numbers of particles smaller than 100.

<Experiment 2>

In the apparatus shown in FIG. 1, gases of different types were used as a plasma generation gas supplied from the gas distribution nozzle 38, and the inner surface of the quartz cover 72 of the gas exciting section 66 was examined in terms of the etched level. In this experiment, the process pressure was set at 0.21 Torr, the process temperature was set at 450° C., and the RF power was set at 500 watts. The ground side and hot side of the electrodes 74 and 75 were not switched. As a gas supplied from the gas distribution nozzle 38, H₂, N₂, NH₃, and Ar (two different process times) were used, and the amount of etching and the amount of deposition to the cover 72 were measured for the respective gases. It should be noted that different process times were used for the respective gases.

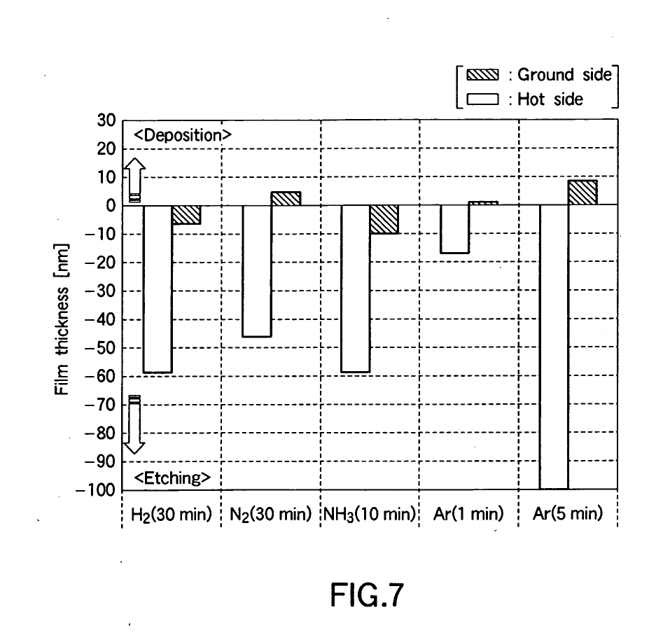

FIG. 7 is a graph showing the gas type dependency of the amount of etching to the quartz cover 72 of the gas exciting section 66. As shown in FIG. 7, a portion of the cover on the ground side slightly suffered etching or deposition in all the gases. On the other hand, a portion of the cover on the hot side suffered severe etching in all the gases, although the etching amount differed depending on the gas type.

<Modification>

In the embodiment described above, the quartz cover 72 (plasma generation box) of the gas exciting section 66 projects outward from the process container 4. Alternatively, the present invention may be applied to an apparatus including a gas exciting section disposed inside a process container.

In the embodiment described above, the main control section 60 and controller 88 are used to automatically switch the switches 86A and 86B of the switching circuit 84. Alternatively, it may be arranged to manually switch the switches 86A and 86B. The switching circuit 84 may have a structure to manually switch the connection of the feed lines 78 and 80 between cross connection and parallel connection.

In the embodiment described above, the second process gas contains a nitriding gas for film formation of a silicon nitride film (SiN or SiN₂). Alternatively, the present invention may be similarly applied to film formation of a silicon oxynitride film or silicon oxide film. Where the present invention is applied to formation of a silicon oxynitride film, an oxynitriding gas, such as dinitrogen oxide (N₂O) or nitrogen oxide (NO), may be used in place of the nitriding gas. Where the present invention is applied to formation of a silicon oxide film, an oxidizing gas, such as oxygen (O₂) or ozone (O₃), may be used in place of the nitriding gas.

In addition to the process gases described above, an impurity gas, such as BCl₃ gas, for introducing an impurity, and/or a carbon hydride gas, such as ethylene, for adding carbon may be further used. The present invention may be applied to another film formation process, such as an ordinary plasma CVD (Chemical Vapor Deposition) process, in place of the ALD process as described above. Further, the present invention may be applied to another plasma process, such as a plasma etching process, plasma oxidation/diffusion process, or plasma reformation process, in place of a plasma film formation process described above. The present invention may be applied to another target substrate, such as a glass substrate, LCD substrate, or ceramic substrate, in place of a semiconductor wafer described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vertical plasma processing apparatus for a semiconductor process for performing a plasma process on a plurality of target substrates all together, the apparatus comprising:
a vertically elongated process container having a process field configured to accommodate the target substrates and to be set in an airtight state;
a holder configured to support the target substrates at intervals in a vertical direction inside the process container;
a gas supply system configured to supply a process gas into the process container;
an exhaust system configured to exhaust gas from inside the process container; and
an exciting mechanism configured to turn at least part of the process gas into plasma,
wherein the exciting mechanism comprises
a plasma generation box attached to the process container at a position corresponding to the process field to form a plasma generation area airtightly communicating with the process field,
first and second electrodes provided to the plasma generation box and facing each other with the plasma generation area interposed therebetween,
an RF (radio frequency) power supply configured to supply an RF power for plasma generation to the first and second electrodes and comprising first and second output terminals serving as grounded and non-grounded terminals, respectively,
first and second feed lines connecting the first and second electrodes to the first and second output terminals, and
a switching mechanism configured to switch between a first state where the first electrode is connected to the first output terminal and the second electrode is connected to the second output terminal, and a second state where the first electrode is connected to the second output terminal and the second electrode is connected to the first output terminal.

2. The apparatus according to claim 1, wherein the plasma generation box includes a quartz inner surface.

3. The apparatus according to claim 1, wherein the plasma generation box is attached outside the process container, and the first and second electrodes are disposed outside the plasma generation box.

4. The apparatus according to claim 1, wherein the switching mechanism comprises first and second switches disposed on the first and second feed lines, and a switching controller configured to simultaneously operate the first and second switches.

5. The apparatus according to claim 1, wherein the apparatus further comprises a control section configured to control an operation of the apparatus and preset to switch the first and second states of the exciting mechanism during one batch process performed on the target substrates.

6. The apparatus according to claim 1, wherein the apparatus further comprises a control section configured to control an operation of the apparatus and preset not to switch the first and second states of the exciting mechanism during one batch process performed on the target substrates.

7. The apparatus according to claim 6, wherein the control section is preset to switch the first and second states of the exciting mechanism after a plurality of batch processes are performed.

8. The apparatus according to claim 1, wherein the process gas comprises first and second film formation gases for forming a thin film on the target substrates, and the gas supply system comprises a first film formation gas supply system configured to supply the first film formation gas to the process field not through the plasma generation area, and a second film formation gas supply system configured to supply the second film formation gas to the process field through the plasma generation area.

9. The apparatus according to claim 8, wherein the apparatus further comprises a control section configured to control an operation of the apparatus and preset to perform a film formation process for forming the thin film on the target substrates inside the process container, and the film formation process is arranged to repeatedly perform, a predetermined number of times, a cycle that alternately comprises supplying the first film formation gas to the process field and supplying the second film formation gas to the process field while exciting the second film formation gas by the exciting mechanism.

10. The apparatus according to claim 8, wherein the first film formation gas comprises a silane family gas, and the second film formation gas comprises a gas selected from the group consisting of a nitriding gas, an oxynitriding gas, and an oxidizing gas.

11. A method for using a vertical plasma processing apparatus for a semiconductor process for performing a plasma process on a plurality of target substrates all together,
the apparatus comprising
a vertically elongated process container having a process field configured to accommodate the target substrates and to be set in an airtight state,
a holder configured to support the target substrates at intervals in a vertical direction inside the process container,
a gas supply system configured to supply a process gas into the process container,
an exhaust system configured to exhaust gas from inside the process container, and
an exciting mechanism configured to turn at least part of the process gas into plasma,
wherein the exciting mechanism comprises
a plasma generation box attached to the process container at a position corresponding to the process field to form a plasma generation area airtightly communicating with the process field,
first and second electrodes provided to the plasma generation box and facing each other with the plasma generation area interposed therebetween,
an RF (radio frequency) power supply configured to supply an RF power for plasma generation to the first and second electrodes and comprising first and second output terminals serving as grounded and non-grounded terminals, respectively, and
first and second feed lines connecting the first and second electrodes to the first and second output terminals,
the method comprising:
performing a semiconductor process on the target substrates inside the process field by supplying the process gas to the process field while exciting at least part of the process gas into plasma by the exciting mechanism; and
switching between a first state where the first electrode is connected to the first output terminal and the second electrode is connected to the second output terminal, and a second state where the first electrode is connected to the second output terminal and the second electrode is connected to the first output terminal, each of which is used as a state of the exciting mechanism for exciting at least part of the process gas into plasma.

12. The method according to claim 11, wherein the method is arranged to switch the first and second states of the exciting mechanism during one batch process performed on the target substrates.

13. The method according to claim 11, wherein the method is arranged not to switch the first and second states of the exciting mechanism during one batch process performed on the target substrates.

14. The method according to claim 13, wherein the method is arranged to switch the first and second states of the exciting mechanism after a plurality of batch processes are performed.

15. The method according to claim 11, wherein the process gas comprises first and second film formation gases for forming a thin film on the target substrates, and the method is arranged to perform a film formation process that comprises supplying the first film formation gas to the process field not through the plasma generation area, and supplying the second film formation gas to the process field through the plasma generation area.

16. The method according to claim 15, wherein the film formation process is arranged to repeatedly perform, a predetermined number of times, a cycle that alternately comprises supplying the first film formation gas to the process field and supplying the second film formation gas to the process field while exciting the second film formation gas by the exciting mechanism.

17. The method according to claim 15, wherein the first film formation gas comprises a silane family gas, and the second film formation gas comprises a gas selected from the group consisting of a nitriding gas, an oxynitriding gas, and an oxidizing gas.

18. The method according to claim 11, wherein switching of the first and second states is performed by an operation of a switching circuit under control of a switching controller.
